(19) United States
(12) Patent Application Publication
(10) Pub. No.: US 2017/0062025 A1
(43) Pub. Date: Mar. 2, 2017

(54) MEMORY SYSTEM INCLUDING PLURAL MEMORY DEVICES FORMING PLURAL RANKS AND MEMORY CONTROLLER ACCESSING PLURAL MEMORY RANKS AND METHOD OF OPERATING THE MEMORY SYSTEM

(71) Applicant: SAMSUNG ELECTRONICS CO., LTD., Suwon-si (KR)

(72) Inventors: Dong-uk KIM, Seoul (KR); Hanjoon KIM, Namyangju-si (KR)

(73) Assignee: SAMSUNG ELECTRONICS CO., LTD., Suwon-si (KR)

(21) Appl. No.: 15/182,038

(22) Filed: Jun. 14, 2016

(30) Foreign Application Priority Data
Sep. 2, 2015 (KR) 10-2015-0124264

(51) Int. Cl. G11C 7/10; G06F 12/02

(52) U.S. Cl. CPC G11C 7/1072; G06F 12/023

(57) ABSTRACT

The inventive concept relates to a memory system. The memory system of the inventive concept includes a plurality of memory devices included in a plurality of memory groups, and a memory controller configured to independently access the memory groups. The memory controller is configured to allocate allocation units having different sizes to different memory groups and perform a write operation based on an allocation unit of one of the memory groups.

### CROSS-REFERENCE TO RELATED APPLICATION

This application claims priority from Korean Patent Application No. 10-2015-0124264, filed on Sep. 2, 2015, the disclosure of which is hereby incorporated in its entirety by reference.

### BACKGROUND

1. Field

Apparatuses and methods consistent with exemplary embodiments relate to semiconductor memories, and more particularly, to a memory system including memory devices and a memory controller, and a method of operating the memory system.

2. Description of the Related Art

A memory system is used to store user data and/or to provide stored data to a user. A memory system may be used in a variety of personal devices such as a smart phone, a smart pad, a personal computer, etc. and may be used in an enterprise device such as a data center.

The data center includes an application server, a database server, and a cache server. The application server may process a request from a client and may access the database server and/or the cache server according to the request from the client. The database server may store data processed by the application server or may provide the stored data to the application server according to a request from the application server. The cache server temporarily stores data stored in the database server and may respond to a request from the application server at a higher response speed than that of the database server.

A memory system is provided to the application server, the database server, and the cache server. The memory system is provided to the data center on a larger scale and thereby consumes a large amount of power. Power consumption of the memory system occupies the majority of power consumption of the data center. Thus, to reduce power consumption of the data center, an apparatus and a method capable of reducing power consumption of the memory system are desirable.

### SUMMARY

According to an aspect of an exemplary embodiment, there is provided a memory system including: a plurality of memory devices included in a plurality of memory groups; and a memory controller configured to independently access the memory groups, wherein the memory controller is configured to allocate allocation units having different sizes to different memory groups and perform a write operation based on an allocation unit of one of the memory groups.

According to an aspect of another exemplary embodiment, there is provided a method of operating a memory system, the memory system including a plurality of memory devices, included in a first memory group and a second memory group, and a memory controller, the method including: receiving, by the memory controller, a write request; writing, by the memory controller, write data to the first memory group in response to a size of the write data associated with the write request being equal to or smaller than a reference size; and writing, by the memory controller, the write data to the second memory group in response to the size of write data associated with the write request being greater than the reference size, wherein the first memory group and the second memory group enter a sleep mode independently of each other.

According to an aspect of still another exemplary embodiment, there is provided a memory controller including: an interface configured to connect to a plurality of memory devices; and a memory allocator, implemented by at least one hardware processor, configured to manage storage spaces of the plurality of memory devices according to ranks, wherein a rank to which write data is to be stored is determined according to a size of the write data, and each rank is accessed by the memory controller independently of each other.

### BRIEF DESCRIPTION OF THE DRAWINGS

The above and/or other aspects will be more apparent by describing certain example embodiments with reference to the accompanying drawings.

FIG. 1 is a block diagram illustrating a memory system according to an exemplary embodiment.

FIG. 2 is a flowchart illustrating a method in which a memory allocator organizes first through fourth ranks according to an exemplary embodiment.

FIG. 3 illustrates an example of slab classes set by a memory allocator according to an exemplary embodiment.

FIG. 4 illustrates an example of organizing first through fourth ranks based on first through fourth slab classes according to an exemplary embodiment.

FIG. 5 is a flowchart illustrating a method of allocating a slab to write data according to an exemplary embodiment.

FIGS. 6A and 6B illustrate an example of accessing ranks when slab classes are not organized according to ranks.

FIGS. 7A and 7B illustrate an example of accessing ranks when slab classes are organized according to ranks according to an exemplary embodiment.

FIG. 8 is a block diagram illustrating a memory allocator according to an exemplary embodiment.

FIG. 9 is a table illustrating an example of an invalidation address stored in an invalidation register according to an exemplary embodiment.

FIG. 10 is a table illustrating an example of a previous index stored in a previous index register according to an exemplary embodiment.

FIG. 11 is a table illustrating an example of an address table according to an exemplary embodiment.

FIG. 12 is a flowchart illustrating a method of allocating a slab using an invalidation address, a previous index and an address table according to an exemplary embodiment.

FIG. 13 is a block diagram illustrating an application example of a memory system of FIG. 1.

FIG. 14 illustrates a computer network including a memory system according to an exemplary embodiment.

### DETAILED DESCRIPTION

Exemplary embodiments will be described more fully hereinafter with reference to the accompanying drawings. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. In the drawings, the size and relative sizes of layers and regions may be exaggerated for clarity. Like numbers refer to like elements throughout.

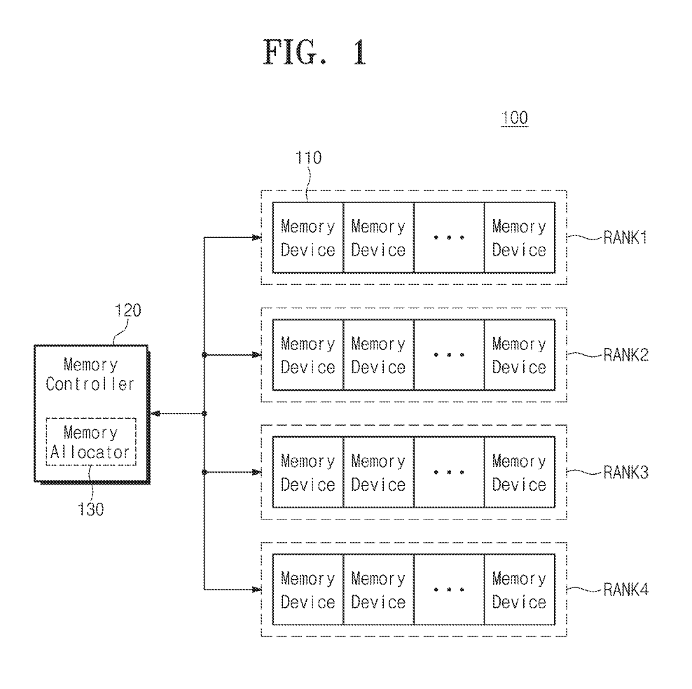

FIG. 1 is a block diagram illustrating a memory system 100 according to an exemplary embodiment. Referring to FIG. 1, the memory system 100 includes a plurality of memory devices 110 and a memory controller 120.

The memory devices 110 may perform a write or read operation according to a control of the memory controller 120. The memory devices 110 may include a volatile memory such as a dynamic random access memory (DRAM), a static RAM (SRAM), etc. or a nonvolatile memory such as a flash memory, a phase-change random access memory (PRAM), a ferroelectric random access memory (FRAM), a magnetic random access memory (MRAM), a resistive random access memory (RRAM), etc.

The memory devices 110 may form a plurality of memory groups. The memory groups may process an external request independently of each other and may enter a sleep mode independently of each other. For brevity of description, it is assumed that the memory devices 110 form first through fourth ranks RANK1, RANK2, RANK3, and -RANK4. The first through fourth ranks RANK1-RANK4 may correspond to a dual in-line memory module (DIMM) interface. However, the inventive concept is not limited to the DIMM interface.

Each rank may be accessed by the memory controller 120 independently of each other. The memory devices 110 that belong to a selected rank may be accessed in parallel at the same time by the memory controller 120. The memory devices 110 that form the first through fourth ranks RANK1-RANK4 may have the same structure and/or the same characteristic. For example, the memory devices 110 may be homogeneous memory devices. For brevity of description, it is assumed that the memory devices 110 form the first through fourth ranks RANK1-RANK4, but the number of ranks is not limited.

The memory controller 120 may access the memory devices 110 by each rank unit according to a request from an external host device. For example, the memory controller 120 may select a rank among the first through fourth ranks RANK1-RANK4 according to a request from the external host device. The memory controller 120 may access the memory devices 110 of a selected rank. For example, the memory controller 120 may access the memory devices 110 of the selected rank in parallel at the same time. In the case in which the number of input/output lines of each memory device is eight and the number of the memory devices 110 of the selected rank is nine, the memory controller 120 may access the memory devices 110 of the selected rank at the same time through 72 input/output lines. For example, the memory controller 120 may access the first through fourth ranks RANK1-RANK4 and the memory devices 110 based on a DIMM interface method.

The memory controller 120 includes a memory allocator 130. The memory allocator 130 may organize storage spaces of the first through fourth ranks RANK1-RANK4 according to a size of write data. The memory allocator 130 may allocate a rank among the first through fourth ranks RANK1-RANK4 to write data being received from the external host device based on an organization of the first through fourth ranks RANK1-RANK4. The memory allocator 130 will be described in further detail below. The memory controller 120 may further include an interface (not shown) connected to the memory devices 110, and data is interfaced between the memory controller and the memory devices 110 via the interface.

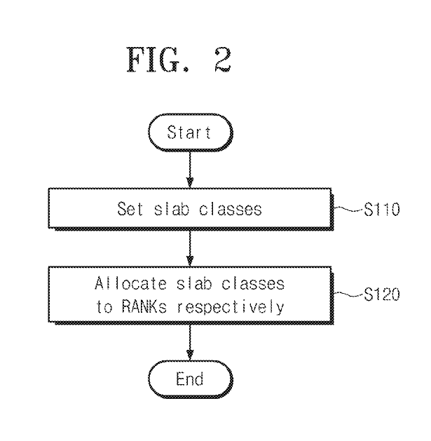

FIG. 2 is a flowchart illustrating a method of organizing first through fourth ranks by a memory allocator according to an exemplary embodiment. The method of FIG. 2 may be performed when the memory system 100 is initialized or the memory system 100 is restructured according to a request from the external host device. For example, the memory allocator 130 may organize the first through fourth ranks RANK1-RANK4 based on an allocation unit (or allocation size) and an allocation class.

Each allocation unit (or each allocation size) may be a storage space distinguished by a beginning address and an ending address, a beginning address and a sector count, a beginning address and an offset, an index and a segment, etc. Allocation units (or allocation sizes) having the same size may belong to the same allocation class. Allocation units (or allocation sizes) having different sizes may belong to allocation classes different from one another. For brevity of description, the allocation unit (or allocation size) is described as a slab and the allocation class is described as a slab class. However, the inventive concept is not limited to the slab and the slab class.

Referring to FIGS. 1 and 2, in operation S110, the memory allocator 130 sets a slab class. For example, each slab class may include homogeneous slabs having the same size. Slab classes different from one another may include heterogeneous slabs having sizes different from one another. Each slab may be a basic unit allocated to write data.

For example, the memory allocator 130 may determine a first size of the slab. The memory allocator 130 may form a first slab class including slabs having the first size. The memory allocator 130 may determine a form factor. For example, the memory allocator 130 may determine a form factor of ‘2’. The memory allocator 130 may multiply the first size by the form factor to determine a second size. The memory allocator 130 may form a second slab class including slabs having the second sizes. Similarly, the memory allocator 130 may multiply (k−1)-th (k being a positive integer) size by the form factor to determine a k-th size. The memory allocator 130 may form a k-th slab class including slabs having the k-th size. The number of the form factors and the slab classes may be adjusted and is not limited.

In operation S120, the memory allocator 130 allocates slab classes to the first through fourth ranks RANK1-RANK4. For example, the memory allocator 130 may allocate one slab class to one or more ranks. As another example, the memory allocator 130 may allocate one or more slab classes to one rank.

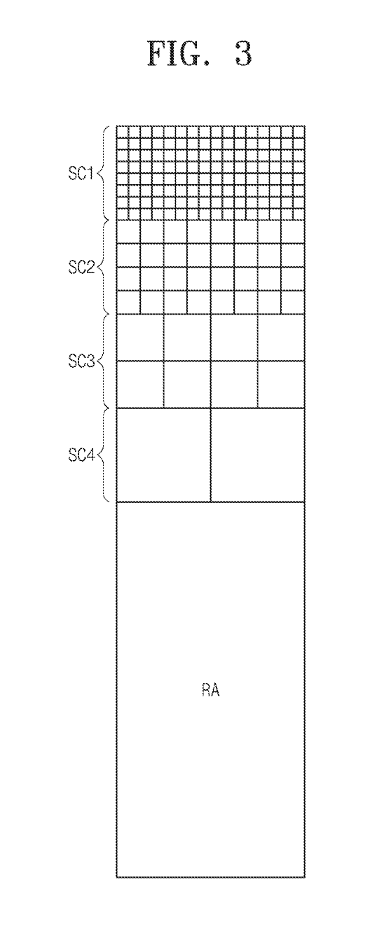

FIG. 3 illustrates an example of slab classes set by a memory allocator. In FIG. 3, slab classes are set in a virtual or logical storage space of the memory devices 110.

Referring to FIGS. 1 and 3, the memory allocator 130 may set first through fourth slab classes SC1-SC4 in the virtual or logical storage space of the memory devices 110. The memory allocator 130 may set the first slab class SC1 including slabs having the smallest size. The memory allocator 130 may multiply a size of each slab of the first slab class SC1 by the form factor to set the second slab class SC2. For illustrative purposes, the form factor is described as ‘4’ in the present embodiment but is not limited thereto. The memory allocator 130 may multiply a size of each slab of the second slab class SC2 by the form factor to set the third slab class SC3. The memory allocator 130 may multiply a size of each slab of the third slab class SC3 by the form factor to set the fourth slab class SC4. Regardless of a size of each slab, the first through fourth slab classes SC1-SC4 may have the same size.

A reserve area (RA) to which the first through fourth slab classes SC1-SC4 are not allocated may exist. For example, the reserve area (RA) may be used to enlarge a slab class having an insufficient storage space among the first through fourth slab classes SC1-SC4.

For example, the reserve area (RA) may be an area that is directly accessible by the external host device. The external host device may allocate a page to the reserve area (RA) and may write data to the allocated page. A size of the page may be greater than a size of each slab. For example, in the case in which a size of write data to be written by the external host device in the memory system 100 corresponds to the page, the external host device may allocate a page to the reserve area (RA). In the case in which a size of write data to be written by the external host device in the memory system 100 corresponds to one of slabs of the first through fourth slab classes SC1-SC4, the external host device may request the memory allocator 130 for an allocation of a slab.

As another example, the reserve area (RA) may not exist. The memory allocator 130 may set slab classes and slabs in the whole virtual (or logical) storage space of the memory devices 110. When an external host requests writing of write data, the memory allocator 130 may allocate one slab, among slabs of organized slab classes, to the write data. In this case, the memory controller 120 may prohibit the external host device from being directly allocated to a page in the memory system 100.

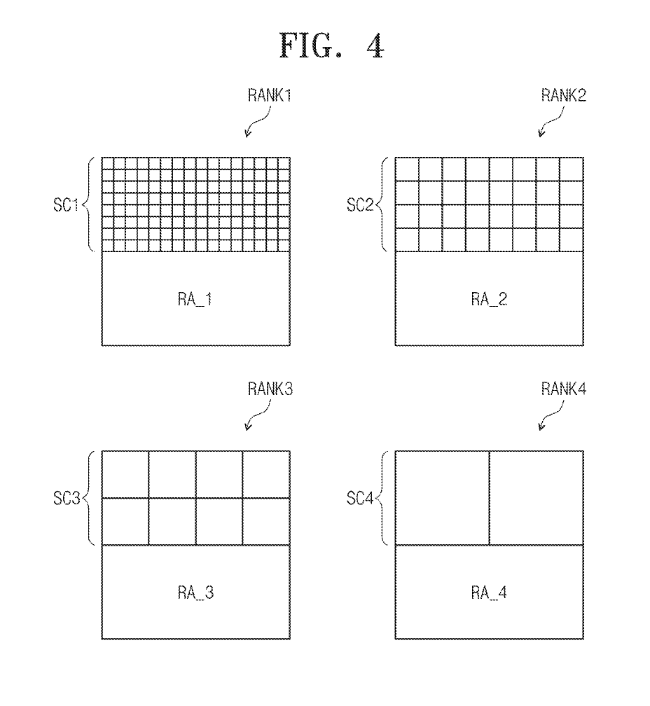

FIG. 4 illustrates an example of organizing first through fourth ranks RANK1-RANK4 based on first through fourth slab classes SC1-SC4 according to an exemplary embodiment. In an exemplary embodiment of FIG. 4, it is described that one slab class belongs to one rank.

Referring to FIG. 4, the first slab class SC1 and a first reserve area RA_1 may be allocated to the first rank RANK1. The second slab class SC2 and a second reserve area RA_2 may be allocated to the second rank RANK2. The third slab class SC3 and a third reserve area RA_3 may be allocated to the third rank RANK3. The fourth slab class SC4 and a fourth reserve area RA_4 may be allocated to the fourth rank RANK4.

The memory allocator 130 may allocate slab classes different from one another to ranks different from one another. That is, the memory allocator 130 may enable independent and separate accesses to slab classes different from one another.

In FIG. 4, one slab class is illustrated as corresponding to one rank. However, one slab class may be allocated to a plurality of ranks. Two or more slab classes may be allocated to one rank. In this case, the two or more slab classes being allocated to one rank may be slab classes close to one another. For example, a (k−1)-th slab class and a kth slab class closest to each other may be allocated to one rank.

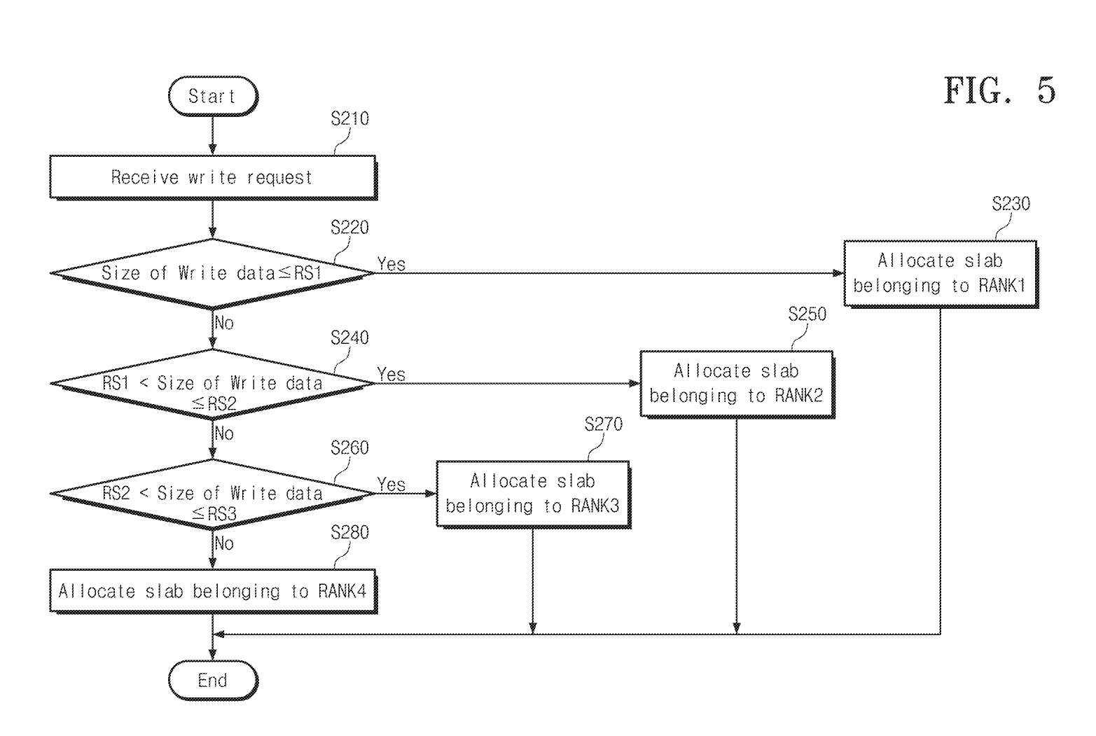

FIG. 5 is a flowchart illustrating a method in which a memory allocator 130 allocates a slab to write data. Referring to FIGS. 1 and 5, in operation S210, the memory controller 120 receives a write request. The write request may be received in conjunction with write data or the write request may include write data.

In operation S220, the memory allocator 130 determines whether a size of write data is equal to or smaller than a first reference size RS1. For example, the first reference size RS1 may be a size of each slab of the first slab class SC1.

If a size of write data is equal to or smaller than the first reference size RS1, in operation S230, the memory allocator 130 may allocate a slab that belongs to the first rank RANK1, that is, a slab of the first slab class SC1 to the write data. If a size of the write data is greater than the first reference size RS1, operation S240 is performed.

In operation S240, the memory allocator 130 determines whether a size of the write data is equal to or smaller than a second reference size RS2. For example, the second reference size RS2 may be a size of each slab of the second slab class SC2.

If the size of the write data is greater than the first reference size RS1 and is equal to or smaller than the second reference size RS2, in operation S250, the memory allocator 130 may allocate a slab that belongs to the second rank RANK2, that is, a slab of the second class SC2 to the write data. If the size of the write data is greater than the second reference size RS2, operation S260 is performed.

In operation S260, the memory allocator 130 determines whether the size of the write data is equal to or smaller than a third reference size RS3. For example, the third reference size RS3 may be a size of each slab of the third slab class SC3.

If the size of the write data is greater than the second reference size RS1 and is equal to or smaller than the third reference size RS3, in operation S270, the memory allocator 130 may allocate a slab that belongs to the third rank RANK3, that is, a slab of the third class SC3 to the write data.

If the size of the write data is greater than the third reference size RS3, operation S280 is performed. In operation S280, the memory allocator 130 may allocate a slab that belongs to the fourth rank RANK4, that is, a slab of the fourth class SC4 to the write data.

As describe with reference to FIGS. 1 through 4, the memory allocator 130 may set different slab classes of different ranks. That is, when different slab classes are accessed, different ranks may be accessed.

The memory system 100 may be used to embody a data structure based on a key-value store. For example, when writing data to the memory system 100, the external host device may transmit a key and a value to the memory system 100. The memory controller 120 may perform a hash operation (or hash function) on the key to generate hash data. For example, the hash data may include information about a location in which the value is to be stored. The memory allocator 130 may select a slab class according to a size of the value. The memory allocator 130 may allocate a slab of the selected slab class to the value and may map the selected slab class or a selected slab of the selected slab class to the hash data. The memory controller 120 may separately store mapping information relating to the hash data. For example, the memory allocator 130 may allocate a slab in which the key and the mapping information of the hash data are to be stored.

When reading data from the memory system 100, the external host device may transmit a key to the memory system 100. For example, the memory controller 120 may perform a hash operation (or hash function) on the key to generate hash data. As another example, the memory controller 120 may read hash data stored by a write operation using the received key. The memory system 100 may read a value from a slab of a slab class which is indicated by the mapping information of the hash data.

In the data structure based on the key-value store, an access frequency may become different depending on a size of the value. That is, an access frequency may become different by a slab class. The memory system 100 respectively sets different slab classes to different ranks. In the memory system 100, an access frequency becomes different according to a rank and a rank having a low access frequency may enter a sleep mode. Thus, power consumption of the memory system 100 is reduced.

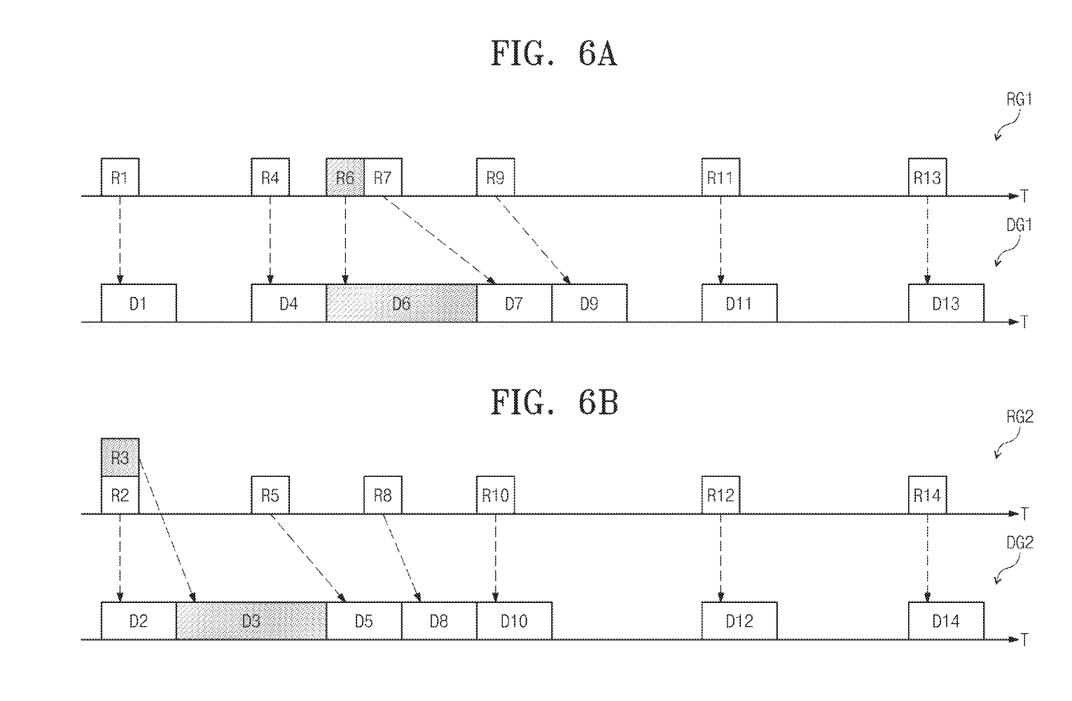

FIGS. 6A and 6B illustrate examples of accessing the ranks in a case where slab classes are not organized according to ranks. In FIG. 6, a horizontal axis indicates time (T).

In the case where slab classes are not organized according to ranks, slabs that belong to one slab class may be dispersively set to a plurality of ranks. Slabs having different sizes may be set in one rank.

Referring to FIGS. 1 and 6A, a first request graph RG1 illustrates an access request with respect to the first rank RANK1 and a first data graph DG1 illustrates data accesses generated in the first rank RANK1. Referring to FIGS. 1 and 6B, a second request graph RG2 illustrates an access request with respect to the second rank RANK2 and a second data graph DG2 illustrates data accesses generated in the second rank RANK2.

A first request R1 may occur with respect to the first rank RANK1 and second and third requests R2 and R3 may occur with respect to the second rank RANK2. The first and second requests R1 and R2 may be an access request with respect to slabs of the first slab class SC1 and the third request R3 may be an access request with respect to a slab of the second slab class SC2.

First data D1 is accessed in the first rank RANK1 according to the first request R1. Second and third data D2 and D3 are accessed in the second rank RANK2 according to the second and third requests R2 and R3.

Next, a fourth request R4 occurs in the first rank RANK1 and a fifth request R5 occurs in the second rank RANK2. The fourth and fifth requests R4 and R5 may correspond to slabs of the first slab class SC1. Fourth data D4 is accessed in the first rank RANK1 according to the fourth request R4. Fifth data D5 is accessed in the second rank RANK2 according to the fifth request R5.

Next, sixth and seventh requests R6 and R7 occur in the first rank RANK1 and an eighth request R8 occurs in the second rank RANK2. The sixth request R6 may correspond to a slab of the second slab class SC2 and the seventh and eighth requests R7 and R8 may correspond to slabs of the first slab class SC1. Sixth and seventh data D6 and D7 are accessed in the first rank RANK1 according to the sixth and seventh requests R6 and R7. Eighth data D8 is accessed in the second rank RANK2 according to the eighth request R8.

Next, a ninth request R9 occurs in the first rank RANK1 and a tenth request R10 occurs in the second rank RANK2. The ninth and tenth requests R9 and R10 may correspond to slabs of the first slab class SC1. Ninth data D9 is accessed in the first rank RANK1 according to the ninth request R9. Tenth data D10 is accessed in the second rank RANK2 according to the tenth request R10.

Next, an eleventh request R11 occurs in the first rank RANK1 and a twelfth request R12 occurs in the second rank RANK2. The eleventh and twelfth requests R11 and R12 may correspond to slabs of the first slab class SC1. Eleventh data D11 is accessed in the first rank RANK1 according to the eleventh R11. Twelfth data D12 is accessed in the second rank RANK2 according to the twelfth request R12.

Next, a thirteenth request R13 occurs in the first rank RANK1 and a fourteenth request R14 occurs in the second rank RANK2. The thirteenth and fourteenth requests R13 and R14 may correspond to slabs of the first slab class SC1. Thirteenth data D13 is accessed in the first rank RANK1 according to the thirteenth request R13. Fourteenth data D14 is accessed in the second rank RANK2 according to the fourteenth request R14.

As illustrated in FIG. 6, an access frequency of slabs of the first slab class SC1 corresponding to a smaller size may be higher than an access frequency of slabs of the second slab class SC2 corresponding to a larger size. In the case where the slab classes SC1 and SC2 are not organized with respect to the ranks RANK1 and RANK2, an access with respect to the ranks RANK1 and RANK2 may dispersively occur in the ranks RANK1 and RANK2.

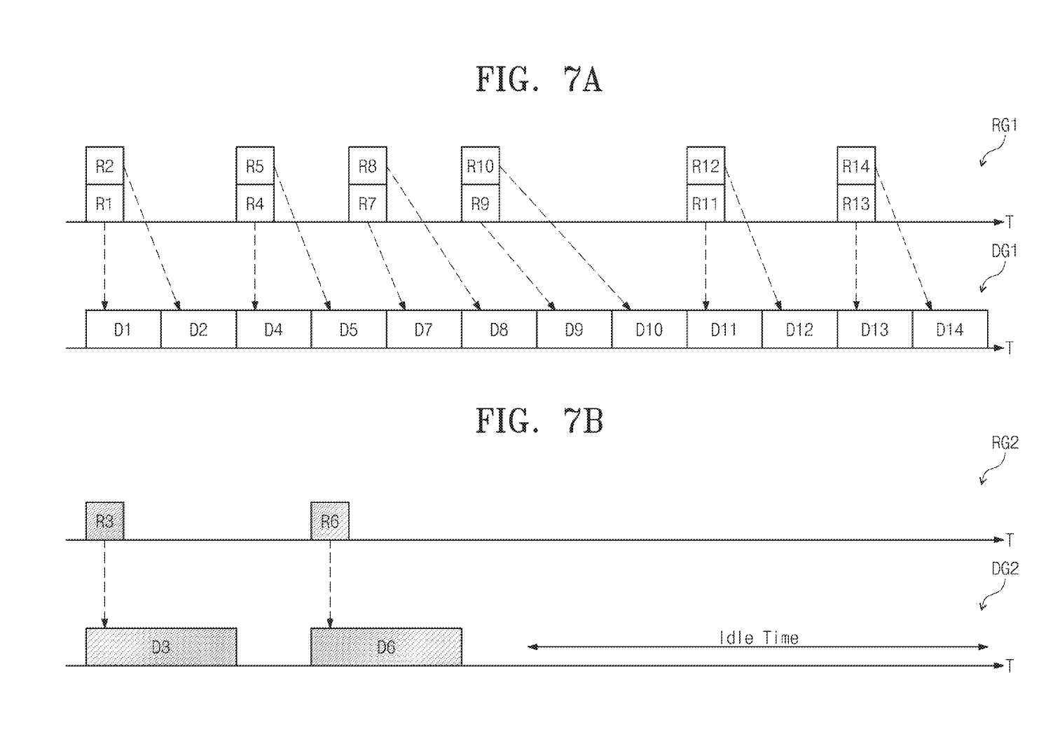

FIGS. 7A and 7B illustrate an example of accessing ranks in a case in which slab classes are organized according to ranks. In FIGS. 7A and 7B, a horizontal axis indicates time (T).

As shown in FIGS. 6A and 6B, in the case in which slab classes are not organized according to ranks, slabs that belong to one slab class may be dispersively set in a plurality of ranks. Slabs having different sizes may be set in one rank.

Referring to FIGS. 1 and 7A, a first request graph RG1 illustrates an access request with respect to the first rank RANK1 and a first data graph DG1 illustrates data accesses generated in the first rank RANK1. Referring to FIGS. 1 and 7B, a second request graph RG2 illustrates an access request with respect to the second rank RANK2 and a second data graph DG2 illustrates data accesses generated in the second rank RANK2.

In FIGS. 7A and 7B, first through fourteenth requests R1-R14 may occur. First through fourteenth data D1-D14 may be accessed according to the first through fourteenth requests R1-R14.

Compared with FIGS. 6A and 6B, slab classes are organized according to ranks in the exemplary embodiment of FIGS. 7A and 7B. For example, the first slab class SC1 may be set in the first rank RANK1 and the second slab class SC2 may be set in the second rank RANK2.

As shown in FIGS. 7A and 7B, when the first and second slab classes SC1 and SC2 are set in the first and second ranks RANK1 and RANK2, respectively, an access frequency of the second rank RANK2 may be reduced. Thus, an idle time occurs in the second rank RANK2 and the second rank RANK2 may enter a sleep mode. That is, power consumption of the memory system 100 may be reduced.

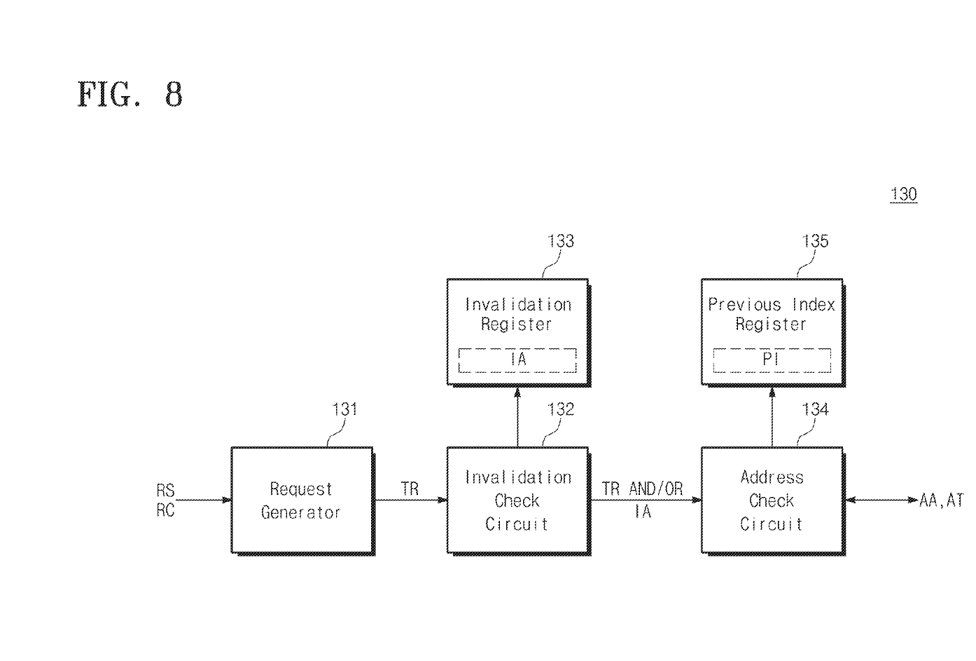

FIG. 8 is a block diagram illustrating a memory allocator 130 according to an exemplary embodiment. Referring to FIGS. 1 and 8, the memory allocator 130 includes a request generator 131, an invalidation check circuit 132, an invalidation register 133, an address check circuit 134 and a previous index register 135.

The request generator 131 may receive a request size RS and a request count RC from the memory controller 120. For example, the request size RS may include information about a size of a slab requested by the memory controller 120. The request count RC may include information about a number of slabs requested by the memory controller 120.

The request generator 131 may output target rank information TR according to the request size RS and the request count RC. For example, the request generator 131 may determine a rank of a slab class to which a slab corresponding to the request size RS belongs and may output target rank information TR indicating the determined rank. The request generator 131 may output target rank information TR as much as the number of times corresponding to a value indicated by the request count RC.

The invalidation check circuit 132 receives the target rank information TR from the request generator 131. The invalidation check circuit 132 may determine whether information associated with a target rank is stored in the invalidation register 133, with reference to the invalidation register 133.

The invalidation register 133 may store information associated with an invalidation address IA. For example, the invalidation register 133 may store at least one address of a slab previously invalidated (or released) for each rank of the memory system 100.

In the case in which the invalidation address IA associated with the target rank is stored in the invalidation register 133, the invalidation check circuit 132 may output the invalidation address IA and the target rank information TR to the address check circuit 134. The invalidation check circuit 132 may delete the output invalidation address IA from the invalidation register 133. In the case in which the invalidation address IA associated with the target rank is not stored in the invalidation register 133, the invalidation check circuit 132 may output the target rank information TR to the address check circuit 134.

The address check circuit 134 may receive the target rank information TR and/or the invalidation address IA. For example, in the case in which the invalidation address IA associated with the target rank is stored in the invalidation register 133, the address check circuit 134 may receive the target rank information TR and the invalidation address IA. In the case in which the invalidation address IA associated with the target rank is not stored in the invalidation register 133, the address check circuit 134 may receive the invalidation address IA.

In the case in which the target rank information TR and the invalidation address IA are received, the address check circuit 134 may read an address table AT of a rank corresponding to the target rank information TR, and by using the address table AT, may determine whether a slab corresponding to the invalidation address IA is a slab that stores invalid data or a slab that stores valid data. In response to determining that the slab corresponding to the invalid address IA stores invalid data, the address check circuit 134 may output the invalidation address IA to an allocated address AA. In response to determining that the slab which the invalidation address IA indicates stores valid data, the address check circuit 134 may ignore the invalid address IA and may allocate a slab using the target rank information TR.

In the case in which the target rank information TR is received without the invalidation address IA or the invalidation address IA received together with the target rank information TR is wrong, the address check circuit 134 may refer to the previous index register 135. The previous index register 135 may store a previous index PI indicating an index of a previously (or immediately previously) allocated slab of a target rank. The previous index register 135 may store a previous index PI of a rank.

In the case in which the previous index PI associated with the target rank is stored in the previous index register 135, the address check circuit 134 may search the address table AT by using the previous index PI. For example, the address check circuit 134 reads the address table AT of a rank corresponding to the target rank information TR and sequentially searches the address table AT from the previous index PI to search for a slab that stores invalid data.

In the case in which the previous index PI associated with the target rank is not stored in the previous index register 135, the address check circuit 134 may read the address table AT of a rank corresponding to the target rank information TR and may search for a slab that stores invalid data from a first index of the address table AT.

The address table AT may be stored in a determined location (or address) of each rank. Thus, the address check circuit 134 performs a read operation with respect to the determined location (or address) of each rank to obtain the address table AT.

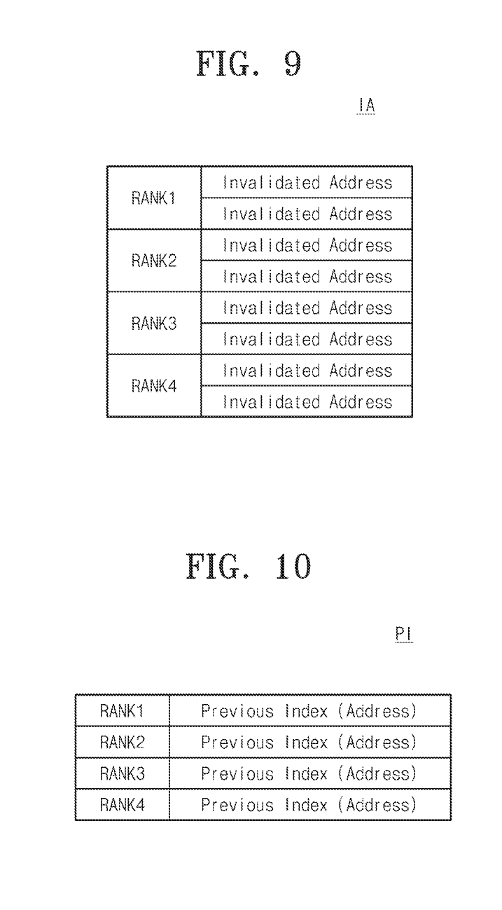

FIG. 9 is a table illustrating an example of an invalidation address stored by an invalidation register 133. Referring to FIG. 9, two invalidation addresses may be stored in each of the first through fourth ranks RANK1-RANK4.

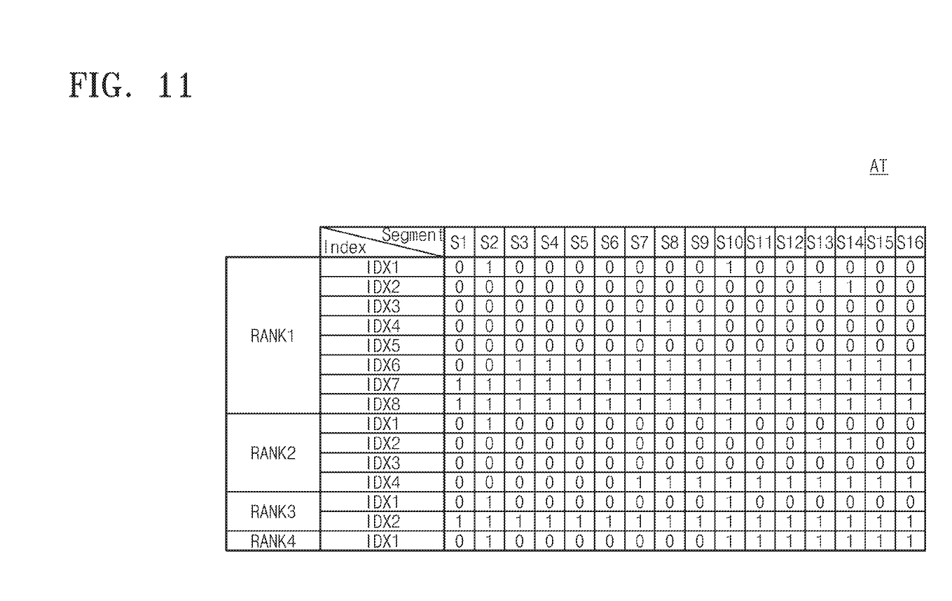

FIG. 10 is a table illustrating an example of a previous index stored in a previous index register 135. Referring to FIG. 10, a previous index or a previous address that is previously (or immediately previously) allocated with respect to the first through fourth ranks RANK1-RANK4 may be stored.

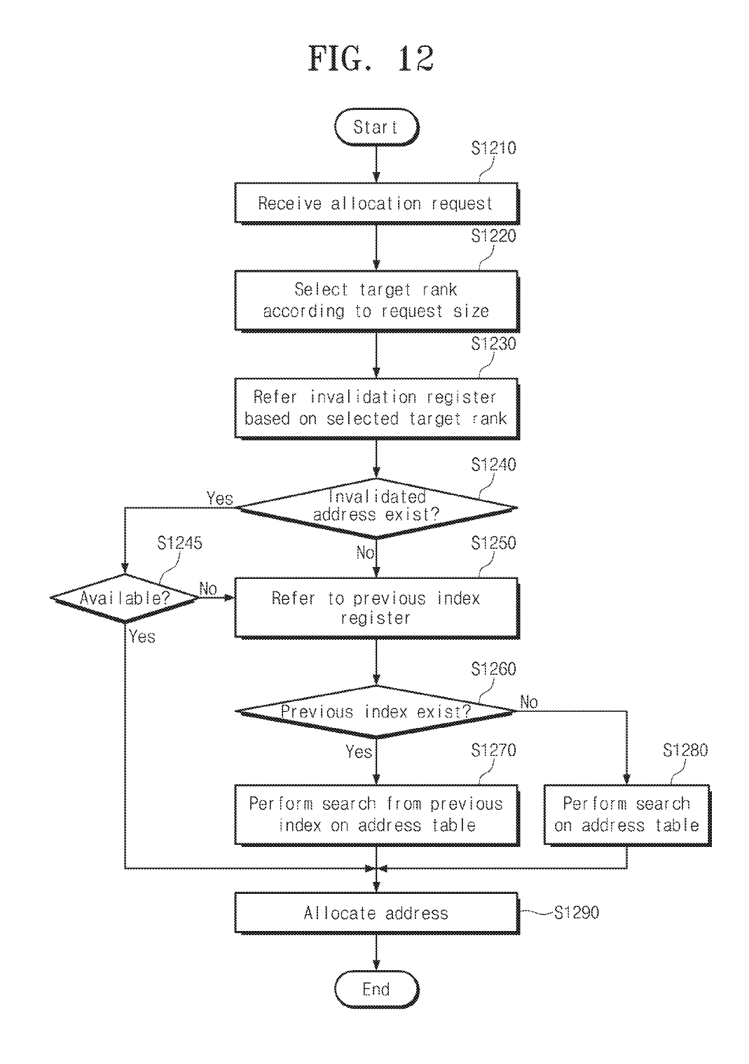

FIG. 11 is a table illustrating an example of an address table AT. Referring to FIG. 11, one bit is allocated to each slab of the first slab class SC1 set in the first rank RANK1. In the case in which each slab stores valid data, a corresponding bit may be set to ‘0’. In the case in which each slab stores invalid data, a corresponding bit may be set to ‘1’.

An address table of each rank may be managed based on an index and a segment. A plurality of segments corresponds to one index. The number of segments of each index may be the same in the first through fourth ranks RANK1-RANK4. For example, the number of segments of each index may correspond to the sum of input/output lines of memory devices of each rank. That is, segments corresponding to each index may correspond to a size at which the memory controller 120 may read from a selected rank through a single read, that is, an input/output bandwidth.

For example, slabs of the first rank RANK1 may be managed based on first through eighth indices IDX1-IDX8 and first through sixteenth segments S1-S16. Slabs of the second rank RANK2 may be managed based on first through fourth indices IDX1-IDX4 and the first through sixteenth segments S1-S16. Slabs of the third rank RANK3 may be managed based on first and second indices IDX1 and IDX2 and the first through sixteenth segments S1-S16. Slabs of the fourth rank RANK4 may be managed based on first index IDX1 and the first through sixteenth segments S1-S16.

Since sizes of slabs that belong to each rank are the same, the slabs may equally split a storage space of each rank to occupy the split storage space, respectively. A physical address of each rank may be calculated from an index value and a segment value of a slab that belongs to each rank.

FIG. 12 is a flowchart illustrating a method in which a memory allocator 130 allocates a slab using an invalidation address IA, a previous index PI and an address table AT. Referring to FIGS. 1, 8 and 12, in operation S1210, the request generator 131 may receive an allocation request. For example, the allocation request may include a request size RS and a request count RC. For brevity of description, it is assumed that the request count RC is 1.

In operation S1220, the request generator 131 selects a target rank according to the request size RS. The request generator 131 may output target rank information TR indicating a selected target rank.

In operations S1230 and S1240, the invalidation check circuit 132 determines whether the invalidation address IA associated with the target rank is stored in the invalidation register 133 with reference to the invalidation register 133.

When it is determined that the invalidation address IA is stored in the invalidation register 133 in operation S1240, it is determined whether a slab corresponding to the invalidation address IA is available in operation S1245. For example, the address check circuit 134 may determine whether a slab corresponding to the invalidation address IA stores valid data with reference to the address table AT. When the slab corresponding to the invalidation address IA does not store valid data, it is determined that the slab corresponding to the invalidation address IA is available. Next, the slab corresponding to the invalidation address IA is selected and the method proceeds to operation S1290. When the slab which the invalidation address IA indicates stores valid data, it is determined that the slab corresponding to the invalidation address IA is unavailable and the method proceeds to operation S1250.

In the case in which the invalidation address IA is not stored or the invalidation address IA is wrong, operations S1250 and S1260 are performed. In operations S1250 and S1260, the address check circuit 134 determines whether a previous index PI exists with reference to the previous index register 135. When it is determined that the previous index PI associated with the target rank is stored in the previous index register 135 in operation S1260, the address check circuit 134 searches for a slab that stores invalid data from the previous index PI in the address table AT in operation S1270. The address check circuit 134 may select the searched slab. When it is determined that the previous index PI associated with the target rank is not stored in the previous index register 135 in operation S1260, the address check circuit 134 searches for a slab that stores invalid data from a first index in the address table AT in operation S1280. The address check circuit 134 may select the searched slab.

Next, in operation S1290, the address check circuit 134 may allocate an address of the selected slab.

As described above, in the case in which the invalidation address IA correctly indicating a previously invalidated slab exists, a search in the address table AT is not performed. Thus, a speed of slab selection may be improved.

In the case in which data begins to be written to each rank, invalid slabs are concentrated in indices of a later part of each rank as illustrated in FIG. 11. In this case, when the address table AT is searched with reference to the previous index PI, a speed of slab selection may be improved.

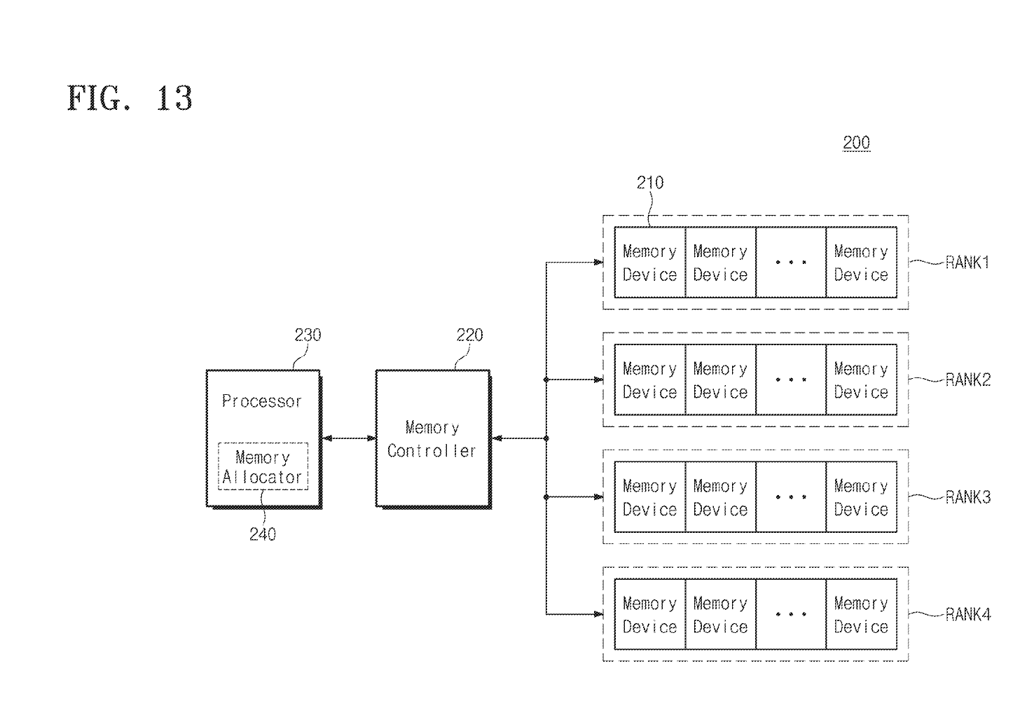

FIG. 13 is a block diagram illustrating an application example of a memory system 100 of FIG. 1. Referring to FIG. 13, a memory system 200 includes memory devices 210 forming first through fourth ranks RANK1-RANK4, a memory controller 220 and a processor 230.

A memory allocator 240 is provided to the processor 230 and not provided to the memory controller 220. For example, the memory allocator 240 may be embodied in software to be executed by the processor 230. For example, the memory allocator 240 may be embodied as a part of a buddy allocator to be executed by the processor 230.

The processor 230 may directly manage storage spaces of the memory devices 210 through the memory controller 220. The memory controller 220 may physically control the memory devices 210 according to a control of the processor 230. The memory allocator 240 may set slab classes in the storage spaces of the memory devices 210 through the memory controller 220. The memory allocator 240 may organize slab classes with respect to the first through fourth ranks RANK1-RANK4 through the memory controller 220.

In the exemplary embodiments described above, the inventive concept has been described with reference to examples such as the slab, the slab class and the slab allocator. However, the inventive concept is not limited thereto. For example, the inventive concept may be applied to memory systems allocating storage spaces having different allocation sizes (or allocation units) according to memory allocation requests corresponding to different allocation sizes (or allocation units).

In the exemplary embodiments described above, the different allocation sizes (or allocation units) have been described to be organized according to ranks (e.g., different ranks). However, the inventive concept is not limited to this. For example, according to an exemplary embodiment, different allocation sizes (or allocation units) may be organized in memory groups (e.g., different memory groups).

For example, different memory groups may independently enter a sleep mode. In other words, a second memory group may enter a sleep mode regardless of whether a first memory group is in a sleep mode or in a normal mode. Any one of a first state in which the first memory group is in a normal mode and the second memory group is in a normal mode, a second state in which the first memory group is in a sleep mode and the second memory group is in a normal mode, a third state in which the first memory group is in a normal mode and the second memory group is in a sleep mode, and a fourth state in which the first memory group is in a sleep mode and the second memory group is in a sleep mode may occur in the first and second memory groups.

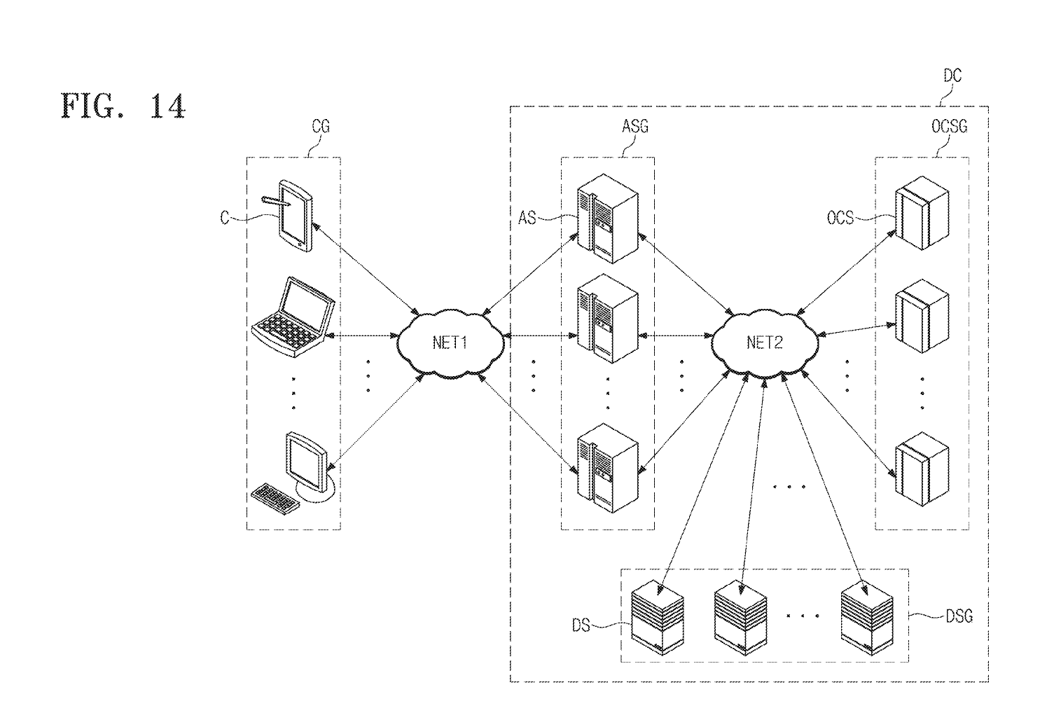

FIG. 14 illustrates a computer network including a memory system 100 or 200 according to an exemplary embodiment. Referring to FIG. 14, client devices C of a client group CG may communicate with a data center DC through a first network NET1. The client devices C may include a variety of devices such as a smart phone, a smart pad, a notebook computer, a personal computer, a smart camera, a smart television, etc. The first network NET1 may include an internet.

The data center DC includes an application server group ASG including application servers AS, an object cache server group OCSG including object cache servers OCS, a database server group DSG including database servers DS, and a second network NET2.

The application servers AS may receive a variety of requests from the client devices C through the first network NET1. The application servers AS may store data of which the client devices C request a storage in the database servers DS through the second network NET2. The application servers AS may secure data of which the client devices C request a read from the database servers DS through the second network NET2.

The object cache servers OCS may perform a cache function between the application servers AS and the database servers DS. The object cache servers OCS may temporarily store data being stored in the database servers DS through the second network NET2 or data being read from the database servers DS. In the case in which data which the application servers AS request is stored in the object cache servers OCS, the object cache servers OCS may provide data requested instead of the database servers DS to the application servers AS through the second network NET2.

The second network NET2 may include a local network LAN or an intranet.

The memory system 100 or 200 in accordance with an exemplary embodiment may be applied to any one of the application servers AS, the object cache servers OCS, and the database servers DS. The memory system 100 or 200 in accordance with an exemplary embodiment may be applied to the object cache servers OCS to substantially improve a response speed of the data center DS.

According to some exemplary embodiment of the inventive concept, a rank to which write data is to be stored is determined according to a size of the write data. Since write data of a similar size are stored in the same rank, an access frequency may be concentrated in a specific rank. Thus, a part of a memory system may enter a sleep mode, and a memory system of which power consumption is reduced and a method of operating the memory system are provided.

At least one of the components, elements, modules or units represented by a block as illustrated in the drawings may be embodied as various numbers of hardware, software and/or firmware structures that execute respective functions described above, according to an exemplary embodiment. For example, at least one of these components, elements or units may use a direct circuit structure, such as a memory, a processor, a logic circuit, a look-up table, etc. that may execute the respective functions through controls of one or more microprocessors or other control apparatuses. Also, at least one of these components, elements or units may be specifically embodied by a module, a program, or a part of code, which contains one or more executable instructions for performing specified logic functions, and executed by one or more microprocessors or other control apparatuses. Also, at least one of these components, elements or units may further include or implemented by a processor such as a central processing unit (CPU) that performs the respective functions, a microprocessor, or the like. Two or more of these components, elements or units may be combined into one single component, element or unit which performs all operations or functions of the combined two or more components, elements of units. Also, at least part of functions of at least one of these components, elements or units may be performed by another of these components, element or units. Further, although a bus is not illustrated in the above block diagrams, communication between the components, elements or units may be performed through the bus. Functional aspects of the above exemplary embodiments may be implemented in algorithms that execute on one or more processors. Furthermore, the components, elements or units represented by a block or processing steps may employ any number of related art techniques for electronics configuration, signal processing and/or control, data processing and the like.

Although a few embodiments have been shown and described, it would be appreciated by those skilled in the art that changes may be made in exemplary embodiments without departing from the principles and spirit of the disclosure, the scope of which is defined in the claims and their equivalents.

What is claimed is:

1. A memory system comprising:
a plurality of memory devices included in a plurality of memory groups; and
a memory controller configured to independently access the memory groups,
wherein the memory controller is configured to allocate allocation units having different sizes to different memory groups and perform a write operation based on an allocation unit of one of the memory groups.

2. The memory system of claim 1, wherein in response to a write request, the memory controller is configured to select a memory group, from among the memory groups, according to a size of write data corresponding to the write request and configured to allocate an allocation unit that belongs to the selected memory group to the write data.

3. The memory system of claim 1, wherein the memory controller is configured to manage an address table of each memory group, the address table indicating whether valid data is stored in an allocation unit that belongs to a corresponding memory group.

4. The memory system of claim 3, wherein in response to a write request, the memory controller is configured to select a memory group, from among the memory groups, according to a size of write data corresponding to the write request and configured to search for an allocation unit, in which invalid data is stored, by using an address table of the selected memory group.

5. The memory system of claim 3, wherein the memory controller is configured to manage information of an allocation unit previously allocated to each memory group.

6. The memory system of claim 5, wherein in response to a write request, the memory controller is configured to select a memory group, from among the memory groups, according to a size of write data corresponding to the write request and configured to search for an allocation unit, in which invalid data is stored, with reference to the information of the allocation unit previously allocated to the selected memory group.

7. The memory system of claim 3, wherein the memory controller is configured to manage information of a previously invalidated allocation unit among allocation units that belong to each memory group.

8. The memory system of claim 7, wherein in response to a write request, the memory controller is configured to select a memory group, from among the memory groups, according to a size of write data corresponding to the write request and configured to allocate the previously invalidated allocation unit to the write data using the information of the previously invalidated allocation unit associated with the selected memory group.

9. The memory system of claim 3, wherein the memory controller comprises:
a request generator configured to select a memory group, from among the memory groups, according to a size of write data corresponding to a write request in response to the write request;
an invalidation check circuit configured to perform determining whether a previously invalidated allocation unit exists in the selected memory group, and configured to output one of an address of the previously invalidated allocation unit and information of the selected memory group, according to a result of the determining; and
an address check circuit configured to, in response to an output from the invalidation check circuit, allocate one of the previously invalidated allocation unit and an allocation unit, which is determined to store invalid data in the selected memory group by using an address table of the selected memory group, to the write data.

10. The memory system of claim 1, wherein the memory devices comprise a plurality of dynamic random access memories.

11. The memory system of claim 1, wherein the memory controller is configured to receive a key and a value corresponding to the key, as a write request.

12. The memory system of claim 11, wherein the memory devices and the memory controller are included in an object cache server.

13. A method of operating a memory system, the memory system comprising a plurality of memory devices, included in a first memory group and a second memory group, and a memory controller, the method comprising:
receiving, by the memory controller, a write request;
writing, by the memory controller, write data to the first memory group in response to a size of the write data associated with the write request being equal to or smaller than a reference size; and
writing, by the memory controller, the write data to the second memory group in response to the size of write data associated with the write request being greater than the reference size,
wherein the first memory group and the second memory group enter a sleep mode independently of each other.

14. The method of claim 13, wherein the write request comprises a key and a value corresponding to the write data.

15. The method of claim 13, wherein the memory devices comprise a plurality of dynamic random access memories.

16. A memory controller comprising:
an interface configured to connect to a plurality of memory devices; and
a memory allocator, implemented by at least one hardware processor, configured to manage storage spaces of the plurality of memory devices according to ranks,
wherein a rank to which write data is to be stored is determined according to a size of the write data, and each rank is accessed by the memory controller independently of each other.

17. The memory controller of claim 16, wherein allocation units having the same size are allocated to the same rank and allocation units having different sizes are allocated to different ranks, and
wherein a write operation of the write data is performed based on an allocation unit of a corresponding rank determined according to the size of the write data.

18. The memory controller of claim 17, wherein the memory allocator is configured to allocate the allocation unit to the write data based on whether a previously invalidated allocation unit exists in the determined rank.

19. The memory controller of claim 17, wherein the ranks enter a sleep mode independently of each other.

20. The memory controller of claim 16, wherein the plurality of memory devices comprise a plurality of dynamic random access memories.
